(19) United States
(12) Patent Application Publication
(10) Pub. No.: US 2026/0312569 A1
(43) Pub. Date: Oct. 8, 2026

(54) Device for Matching RF Power into a Rapidly Varying Load

(71) Applicant: JEFFERSON SCIENCE ASSOCIATES, LLC, Newport News, VA (US)

(72) Inventors: ANDREW HUTTON, YORKTOWN, VA (US); ALEX CASTILLA, YORKTOWN, VA (US)

(73) Assignee: JEFFERSON SCIENCE ASSOCIATES, LLC, Newport News, VA (US)

(21) Appl. No.: 19/642,354

(22) Filed: Apr. 8, 2026

Related U.S. Application Data
(60) Provisional application No. 63/785,270, filed on Apr. 8, 2025.

(51) Int. Cl. H03H 11/30; H01P 5/04

(52) U.S. Cl. CPC H03H 11/30; H01P 5/04

(57) ABSTRACT

A stub tuner that can be varied at high speed, less than a millionth of a second, by using ferroelectric rods made of a ceramic, BaTiO3/SrTiO3-Mg instead of a metal post. The change in tuning is achieved using an external electric field to change the permittivity of the ceramic. There are no moving parts, so the FE-FRT can respond to fast changes in the load (up to 10 MHz). The change in tuning is achieved using an external electric field to change the permittivity of the ceramic. Controlling a voltage to the ceramic alters it’s permittivity, changing the effective length of the stub. Use of the stub tuner enables all power from the source to be delivered to the load.

This application claims the benefit of U.S. Application No. 63785270, which was filed on 04/08/2025, of which the contents are incorporated by reference herein in their entirety.

The United States Government may have certain rights to this invention under Management and Operating Contract No. DE-AC05-06OR23177 from the Department of Energy.

### BACKGROUND OF THE INVENTION

A waveguide or coaxial line is the preferred way to connect an RF source to a load. The characteristics of the RF source are usually well known so matching into the waveguide or coaxial line can be accomplished with no reflected power. On the other hand, the load is usually provided by the customer and is often not well-matched causing power to be reflected towards the RF source, which must be protected by a circulator to deflect the power into a load. The result is a loss of RF power and therefore a reduction in the efficiency of the system.

A three-stub tuner is often used to minimize the reflected power (FIG. 1). Each stub consists of a conducting finger (usually made of copper) which can be inserted into the waveguide, creating a discontinuity, which reflects part of the incoming RF power. The resulting wave starts from the stub and the amplitude depends on how far the stub is inserted.

The three stubs are separated by a fraction of the RF wavelength λ; λ/8, λ/4, 3λ/8 or 5λ/8 are common values. The reflected waves from the stubs add to the reflected wave from the load. There is always a condition where the sum of the waves is zero and the reflected wave from the load is canceled. In this condition, all the power is delivered to the load, increasing the efficiency of the system and protecting the RF source. There is a well-defined protocol to calculate the required insertion of the stub tuners using a Smith chart.

However, this only works if the load has a constant impedance, which is often, but not always, true. If the load is varying in time, the best that can be done is to match the stub tuner to the average value.

### BRIEF SUMMARY OF THE INVENTION

The present invention allows the stub tuner to be varied at high speed (less than a millionth of a second) by using ferroelectric rods made of a ceramic, BaTiO3/SrTiO3-Mg instead of a metal post. The change in tuning is achieved using an external electric field to change the permittivity of the ceramic. There are no moving parts, so the FE-FRT can respond to fast changes in the load (up to 10 MHz).

### BRIEF DESCRIPTION OF THE DRAWINGS

FIG. 1 is a conventional (PRIOR ART) three-stub tuner. The three stubs are usually made of copper and are inserted and retracted with a screwdriver.

FIG. 2 is an implementation example of the three-stub tuner according to the current invention. The BaTiO3/SrTiO3-Mg ceramic (20) is shown at the top of the middle stub (22). Applying a voltage to the ceramic alters it’s permittivity, changing the effective length of the stub. This results in a discontinuity that acts like the copper stub in a conventional three-stub-tuner.

FIG. 3 depicts a second implementation example of a three-stub tuner according to the current invention. In either case, the ceramic cancels change in the load characteristics that result in power being reflected towards the RF source. The result is a standing wave in the waveguide between the tuner and the load, whose amplitude depends on the amount of power reflected from the load (FIG. 3).

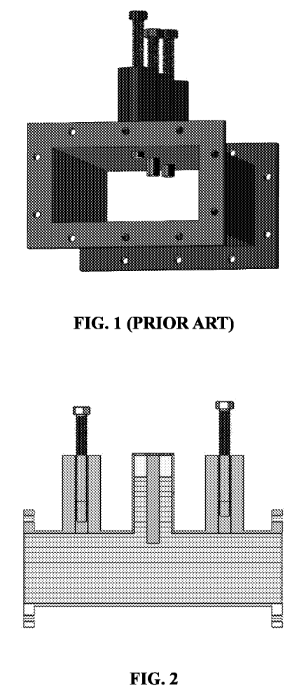

Operation of the three-stub tuner. When the RF wave from the source (1) reaches the three-stub tuner, most of the power is transmitted (2) but a part is reflected (3). When the transmitted power reaches the load, most of the power is transmitted to the load (4) and a part is reflected (5). This reflected power ricochets back and forth the between the load and the three-stub tuner setting up a standing wave that builds up in strength. If the three-stub tuner has been set correctly, the power reflected from the load (5) is cancelled by the reflected power from the three-stub tuner, so the load sees zero reflected power (6). This means that the power from the source (1) is all delivered to the load (4).

### DETAILED DESCRIPTION OF THE INVENTION

One possible implementation is shown in FIG. 2, where a stub is placed external to the waveguide. When the ceramic is unbiased, the RF leakage into the stub is reflected and cancels at the waveguide. There is then no RF discontinuity in the waveguide. When the ceramic is biased, the leakage field is not canceled, causing a discontinuity in the waveguide, whose amplitude is proportional to the current applied to the ceramic. It therefore acts exactly like the mechanical stub in a conventional 3-stub tuner. Note that there may be one, two or three active tuners depending on the application.

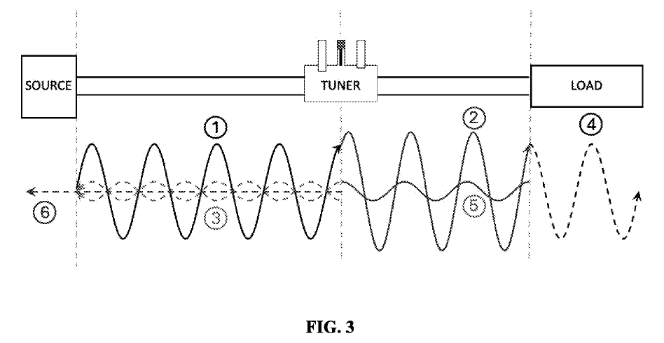

FIG. 3 depicts a similar implementation that can be applied to a coaxial line, commonly used for lower powers.

In either case, the ceramic cancels change in the load characteristics that result in power being reflected towards the RF source. The result is a standing wave in the waveguide between the tuner and the load, whose amplitude depends on the amount of power reflected from the load (see FIG. 3).

### CONTROL SYSTEM

Controlling the tuner requires a feedback system that monitors changes in the matching condition and changes the high voltage to the ceramic to cancel the power reflected towards the RF source.

The ceramic material requires a DC voltage of several kV with a relatively small current. Ideally the nominal operating condition would be with the power supply at half voltage. If the reflection increases, the voltage must go up, if it decreases, it must go down.

A possible control algorithm is as follows. Feedback on the reflected power upstream of the 3-stub tuner is not possible because the nominal condition is zero amplitude making it difficult to sample. To determine whether to increase or decrease the voltage, the phase and/or the amplitude of the reflected power must be determined with respect to the forward power. The forward power phase can be picked up anywhere upstream of the tuner, for example a directional coupler or even the drive phase of the RF source. The pick-up for the reflected power (a directional coupler) should be downstream of the 3-stub tuner. A directional coupler upstream of the tuner is used to confirm that the reflected power has been canceled.

The signal from the reflected power should be mixed with the forward power to determine the phase and amplitude of the reflected power with respect to the forward power. This must be calibrated to determine the sign of the voltage change to be applied. This information would then be fed to the power supply and the voltage applied to the active stub.

For a single active stub, the algorithm is straightforward and only requires a knowledge of the ratio of the reflected power to the forward power. For a tuner with multiple stubs, the phase of the reflected wave with respect to the forward wave is also required to separate the in-phase and out-of-phase components of the reflected wave. Artificial intelligence would be used to determine the best response to a change, based on previous operating experience.

The initial market for a device for matching RF power into a rapidly varying load would be for superconducting cavities in particle accelerators where the load varies with the beam current, which is usually stable over days, while microphonic vibrations cause rapid fluctuations in the cavity resonant frequency (in the range of ~10-50 Hz).

Pulsed accelerating cavities would also profit from the active tuner. As the power in the cavity increases, Lorentz detuning shifts the frequency causing a mismatch, and the reflected power due to this frequency shift could be corrected by an active 3-stub tuner.

Similar arguments hold for RF systems that are used to excite plasmas. When the plasma ignites, the load changes rapidly and the active tuner would maintain the match so all the input power would be delivered to the plasma, independent of the operating conditions.

Three-stub tuners are a staple of microwave engineering applications, and in most cases an active tuner is not necessary. However, all the applications where the load is not stable would profit from an active tuner.

I claim:

1. A method for matching RF power into a rapidly varying load, comprising:
an RF source;
a waveguide connecting the RF source to the load;
inserting a stub tuner into the waveguide between the RF source and the load; and
said stub tuner including a post constructed of a ceramic.

2. The method of claim 1, comprising said post constructed of BaTiO3/SrTiO3-Mg.

3. The method of claim 2, comprising applying an external electric field to the stub tuner to change the permittivity of the ceramic.

4. The method of claim 3, comprising varying the external electric field to the stub tuner at a high speed to change the effective length of the stub and direct all power from the source to be delivered to the load.

5. The method of claim 4, comprising said stub tuner includes a response time to changes in the load of up to 10 MHz.
